(19) United States
(12) Patent Application Publication
(10) Pub. No.: US 2007/0057676 A1
(43) Pub. Date: Mar. 15, 2007

(54) Pulse shunt that allows for the use of light emitting diodes in vehicles that have a pulsed lamp check function in their external lighting system and/or trailers connected thereto

(76) Inventor: Lee Alan Bourgeois, (US)

Correspondence Address: LEE ALAN BOURGEOIS, 13 OXFORD STREET, MITTAGONG, 2575, AU

(21) Appl. No.: 11/530,467

(22) Filed: Sep. 10, 2006

(30) Foreign Application Priority Data
Sep. 12, 2005 (AU) 2005904971

(51) Int. Cl. G01R 31/28

(52) U.S. Cl. 324/528

(57) ABSTRACT

The present invention relates to a pulse shunt that allows for the use of Light Emitting Diodes (LEDs) in vehicles that have a pulsed lamp check function in their external lighting system and/or trailers connected thereto. The present invention shunts the short lamp check voltage pulses, which stops the LEDs, when they are not otherwise illuminated, from flashing even when the ignition has been switched off the pulse shunt can remain active until after the lamp check pulses cease. The present invention allows the lamp check unit of the vehicle to measure a low resistance on the monitored external lighting circuits, where LEDs are fitted, so that ‘lamp failures’ will not be indicated and when a trailer is connected it will be recognised. The present invention may be located on/in a vehicle or trailer or in the wiring between and have either automatic or manual activation.

### CROSS-REFERENCE TO RELATED APPLICATIONS

Foreign application priority data:

12 Sep. 2005 Australia Provisional Patent Application Number 2005904971 A pulse shunt that allows for the use of Light Emitting Diodes in vehicles that have a pulsed lamp check function in their external lighting system and/or trailers connected thereto.

### STATEMENT REGARDING FEDERALLY SPONSORED RESEARCH OR DEVELOPMENT

Not Applicable

### BACKGROUND TO THE INVENTION

Field of endeavour: U.S. Cl. 340-458 Lamp or Circuit Condition IPC Int. Cl.B60Q11 Lamp Outage Indicator Circuits

No references pertaining to this type of invention were found in searches performed using LED, LEDs, Light Emitting Diode, and Light Emitting Diodes in U.S. Australian, U.K., European Japan, and Singapore Databases.

Previously the cold lamp check function in the external lighting system of vehicles and trailers was accomplished by monitoring the current through the filaments of incandescent lamps with a very low applied voltage. This very low voltage did not illuminate either incandescent lamps or LEDs. When LEDs were used with this type of lamp check system it was found necessary to introduce a low resistance in the lighting circuit to provide a sufficient current path to stop ‘lamp failure’ warnings in the vehicle and allow for a trailer, when connected, to be recognised. This type of cold filament monitoring suffers from spurious ‘lamp failure’ warnings, which become more frequent as the electrical connections in the vehicles and trailers age.

The cold pulsed lamp check function has been designed to significantly reduce the number of spurious ‘lamp failure’ warnings as the vehicles and trailers age. However owners and drivers of these vehicles have experienced problems with the operation of their external lighting when replacing incandescent lamps with LEDs and also when connecting trailers that incorporate LEDs in place of incandescent lamps.

In operation lamp check units of this type are continually emitting short pulses of a much higher voltage on the wires to various lamps in the vehicles' external lighting system and to the trailer lighting connector (where fitted). The lamp check unit is ‘awake’, emitting pulses while the vehicle is being driven, and it may continue to remain ‘awake’ for some time after the vehicle has stopped and the ignition has been switched off. This invention can be made to remain active until soon after the lamp check pulses cease.

An incandescent lamp filament has a very low ‘off resistance and it can take between 120 and 250 milliseconds to ‘light up’. The short higher voltage pulses from the lamp check unit are not of long enough duration for the filament to heat up enough to emit light. LEDs ‘light up’ very quickly thus the LEDs will flash with the short lamp check pulses. This invention shunts these short lamp check voltage pulses thus stopping the LEDs, when are not otherwise illuminated, from flashing.

As LEDs have a high resistance they do not absorb the lamp check pulses. This invention incorporates low resistances, as the vehicles’ lamp check unit must distinguish a low resistance so that ‘lamp failures’ will not be indicated by the vehicle and when a trailer is connected it will be recognised. Thus some trailer related vehicle functions (if available) are disabled and others are enabled.

### BRIEF SUMMARY OF THE INVENTION

The present invention relates to a pulse shunt that allows for the use of Light Emitting Diodes (LEDs) in vehicles that have a pulsed lamp check function in their external lighting system and/or trailers connected thereto. The present invention shunts the short lamp check voltage pulses, which stops the LEDs, when they are not otherwise illuminated, from flashing even when the ignition has been switched off the pulse shunt can remain active until after the lamp check pulses cease. The present invention allows the lamp check unit of the vehicle to measure a low resistance on the monitored external lighting circuits, where LEDs are fitted, so that ‘lamp failures’ will not be indicated and when a trailer is connected it will be recognised. The present invention may be located on/in a vehicle or trailer or in the wiring between and have either automatic or manual activation.

### BRIEF DESCRIPTION OF THE SEVERAL VIEWS OF THE DRAWING

The invention will now be described with reference to the following drawings in which:

FIG. 1—is a system circuit diagram showing the connection of a vehicle mounted pulse shunt between the lamp check unit and the vehicle lighting.

FIG. 2—is a system circuit diagram showing the connection of a vehicle mounted pulse shunt between the lamp check unit and a trailer.

FIG. 3—is a system circuit diagram showing the connection to a vehicle of a pulse shunt that is either trailer mounted or located in the wiring to a vehicle.

FIG. 4—is a circuit schematic of the pulse shunt.

### DETAILED DESCRIPTION OF THE INVENTION

It will be appreciated that the following description relates to a particular, preferred implementation. Alternative components, devices and approaches may be used within the general scope of the present invention.

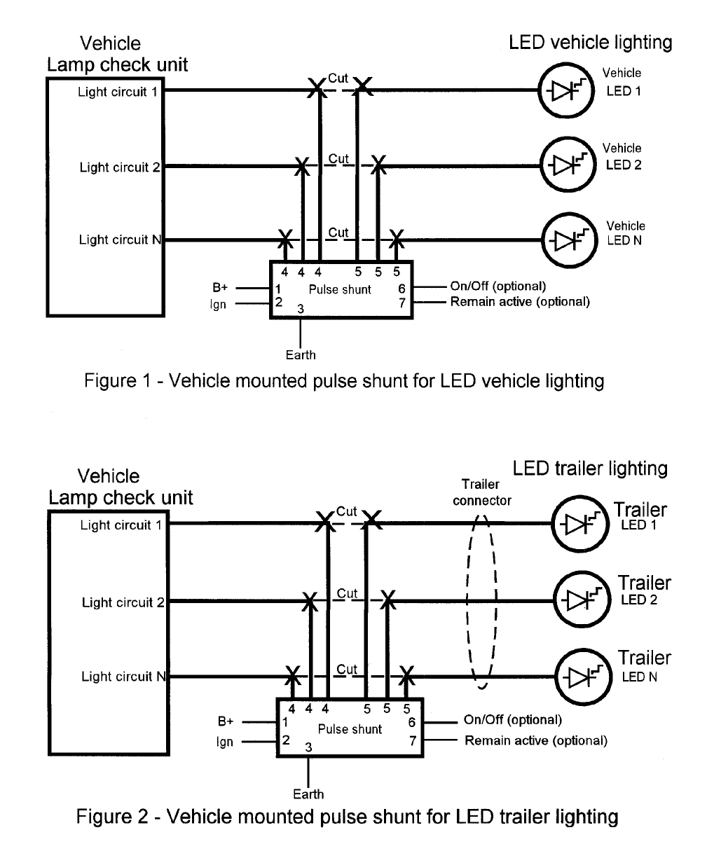

FIG. 1—is a system circuit diagram showing the connection of a vehicle mounted pulse shunt between the lamp check unit and the vehicle lighting.

These connections provide at terminals number:
1—constant battery power
2—ignition switch ‘ON’ sense
3—earth
4—one or more inputs to the pulse shunt from the vehicle lamp check unit
5—one or more outputs from the pulse shunt to the vehicle LED lighting
6—optional on/off switch
7—optional remain active switch

Taken with all of the connections above, the pulse shunt can:
1. From constant battery power supplied to terminal 1 and permanent earth at terminal 3, have the necessary power provided to operate the pulse shunt. With the ignition switched on the pulse shunt can sense this at terminal 2, which optionally activates the pulse shunt if and when required by either manual or automatic means from terminal 6.
2. From one or more inputs at the terminals numbered 4, stop the external lighting LEDs on the vehicle, when they are not otherwise illuminated, from flashing with the short lamp check pulses. A low resistance on each of the inputs absorbs the pulses so that ‘lamp failure’ warnings will be inhibited.
3. From one or more outputs at the terminals numbered 5, illuminate the external lighting LEDs on the vehicle as appropriate from the commands of the vehicle lamp check unit.
4. From terminal 7, optionally be made to remain active, when the ignition has been switched off, until soon after the lamp check pulses from the vehicle lamp check unit cease. This will stop the LEDs from flashing when the lamp check unit in the vehicle is still ‘awake’ and emitting pulses.

FIG. 2—is a system circuit diagram showing the connection of a vehicle mounted pulse shunt between the lamp check unit and a trailer.

These connections provide at terminal number:
1—constant battery power
2—ignition switch ‘ON’ sense
3 earth
4—one or more inputs to the pulse shunt from the vehicle lamp check unit
5—one or more outputs from the pulse shunt to the trailer LED lighting
6—optional on/off switch
7—optional remain active switch

Taken with all of the connections above, the pulse shunt can:
1. From constant battery power supplied to terminal 1 and permanent earth at terminal 3, have the necessary power provided to operate the pulse shunt. With the ignition switched on the pulse shunt can sense this at terminal 2, which optionally activates the pulse shunt if and when required by either manual or automatic means from terminal 6.
2. From one or more inputs at the terminals numbered 4, stop the external lighting LEDs on the trailer, when they are not otherwise illuminated, from flashing with the short lamp check pulses. A low resistance on each of the inputs absorbs the pulses so that ‘lamp failure’ warnings will be inhibited and the trailer will be recognised.
3. From one or more outputs at the terminals numbered 5, illuminate the external lighting LEDs on the trailer as appropriate from the commands of the vehicle lamp check unit.
4. From terminal 7, optionally be made to remain active, when the ignition has been switched off, until soon after the lamp check pulses from the vehicle lamp check unit cease. This will stop the LEDs from flashing when the lamp check unit in the vehicle is still ‘awake’ and emitting pulses.

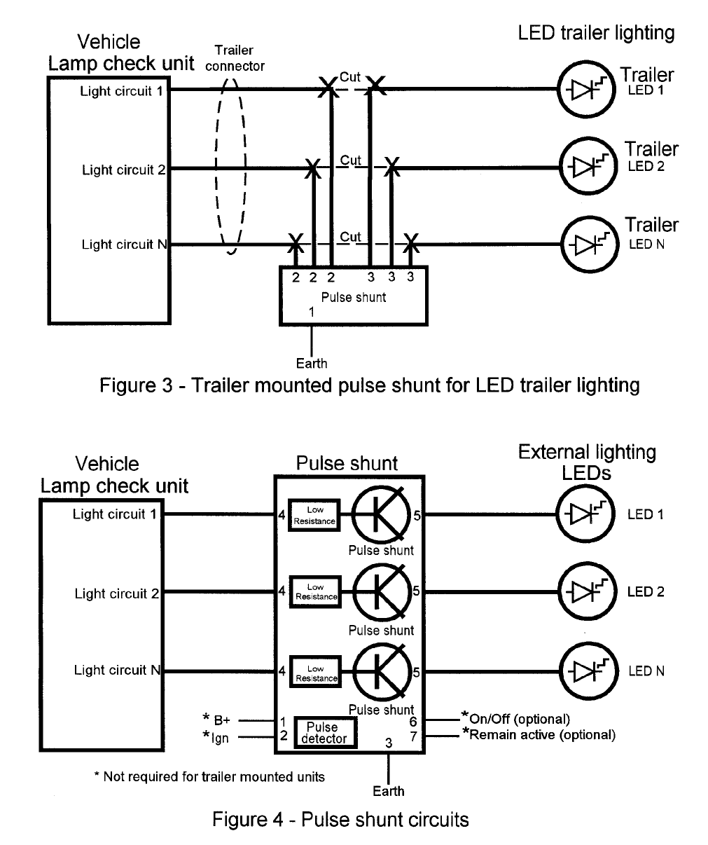

FIG. 3—is a system circuit diagram showing the connection to a vehicle of a pulse shunt that is either trailer mounted or located in the wiring to a vehicle.

These connections provide at terminal number:
3—earth
4—one or more inputs to the pulse shunt from the vehicle lamp check unit
5—one or more outputs from the pulse shunt to the trailer LED lighting

Taken with all of the connections above, the pulse shunt can:
1. From the earth at terminal 3, be provided with the necessary voltage and current return path for the operation of the pulse shunt.
2. From one or more inputs at the terminals numbered 4, provide the necessary power for the operation of the pulse shunt and stop the external lighting LEDs of the trailer, when they are not otherwise illuminated, from flashing with the short lamp check pulses. A low resistance on each of the inputs absorbs the pulses so that ‘lamp failure’ warnings will be inhibited and the trailer will be recognised.
3. From one or more outputs at the terminals numbered 5, illuminate the external lighting LEDs of the trailer as appropriate from the commands of the vehicle lamp check unit.

FIG. 4—is a schematic of the pulse shunt.

These connections provide at terminal number:
1—*constant battery power
2—*ignition switch ‘ON’ sense
3—earth
4—one or more inputs to the pulse shunt from the vehicle lamp check unit
5—one or more outputs from the pulse shunt to the trailer LED lighting
6—*optional on/off switch
7—*optional remain active switch

Taken with all of the connections above, the pulse shunt can:
1. From constant battery power supplied to terminal 1* and permanent earth at terminal 3, have the necessary power provided to operate the pulse shunt. With the ignition switched on the pulse shunt can sense this at terminal 2*, which optionally activates the pulse shunt if and when required by either manual or automatic means from terminal 6*.
2. From one or more inputs at the terminals numbered 4, stop the external lighting LEDs on the trailer, when they are not otherwise illuminated, from flashing with the short lamp check pulses. A low resistance on each of the inputs absorbs the pulses so that ‘lamp failure’ warnings will be inhibited and a trailer, when connected, will be recognised.
3. From one or more outputs at the terminals numbered 5, illuminate the external lighting LEDs as appropriate from the commands of the vehicle lamp check unit.
4. From terminal 7*, optionally be made to remain active, when the ignition has been switched off, until soon after the lamp check pulses from the vehicle lamp check unit cease. This will stop the LEDs from flashing when the lamp check unit in the vehicle is still ‘awake’ and emitting pulses.
   NOTE: For clarity only one low resistance and shunt circuit has been shown. These two portions of the circuitry need to be repeated for each of the number of inputs/outputs that are required in a particular unit. Only one of each of the pulse detector and power control circuits are required for each vehicle mounted unit and none at all for a trailer unit.
   *Not required for trailer units

It will be appreciated that the above description has been given in relation to a preferred embodiment only, and is not meant to be limited to the specifics of the disclosure which may vary in many ways as would be understood by the person skilled in the art, within the scope of the present invention.

I claim:

1. A pulse shunt that allows for the use of Light Emitting Diodes (LEDs), in the place of incandescent lamps, with vehicles that have a pulsed lamp check function in their external lighting system and/or trailers connected thereto wherein the pulse shunt is located on/in a vehicle or trailer or in the wiring between may have either automatic or manual activation so that LEDs, that are otherwise not illuminated, are stopped from flashing with the short lamp check voltage pulses whereas even after the ignition has been switched off the pulse shunt may remain active until after the lamp check pulses cease whilst the low resistance incorporated both inhibits ‘lamp failures’ from being indicated and allows for ‘trailer connected’ recognition by the vehicle.

2. I claim a pulse shunt substantially as herein described with reference to the accompanying four drawings.
